(19) United States
(12) Patent Application Publication
(10) Pub. No.: US 2012/0206894 A1
(43) Pub. Date: Aug. 16, 2012

(54) JUNCTION BOX

(75) Inventors: Chin-Chu Huang, Taoyuan Hsien (TW); Chen-Yu Yu, Taoyuan Hsien (TW); Ren-De Huang, Taoyuan Hsien (TW)

(73) Assignee: DELTA ELECTRONICS, INC., Taoyuan Hsien (TW)

(21) Appl. No.: 13/076,159

(22) Filed: Mar. 30, 2011

(30) Foreign Application Priority Data
Feb. 16, 2011 (TW) 100105174

(51) Int. Cl. H05K 7/02

(52) U.S. Cl. 361/807

(57) ABSTRACT

A junction box includes a casing, plural wire-connecting elements, plural power converting units, a first conductive element and a second conductive element. The casing includes an entrance, a first power output terminal and a second power output terminal. The plural wire pairs are introduced into the casing through the entrance. The plural wire-connecting elements are disposed within the casing and connected with corresponding wire pairs. The plural power converting units are detachably connected with corresponding wire-connecting elements. The power converting units include respective first conductive parts and respective second conductive parts. The first conductive element is connected with the first conductive parts of the power converting units and the first power output terminal. The second conductive element is connected with the second conductive parts of the power converting units and the second power output terminal.

### FIELD OF THE INVENTION

The present invention relates to a junction box, and more particularly to a junction box for use with a solar power module or a photovoltaic module.

### BACKGROUND OF THE INVENTION

Nowadays, the demands on renewable energy are gradually increased. The common renewable energy includes for example solar energy, wind power, tide energy, terrestrial heat, biomass energy, and the like. Among various renewable energy sources, solar energy is expected to replace fossil fuel as a new energy source because it provides clean energy without depletion. In addition, the process of maintaining the solar energy generator is very easy and the operating cost is low. The solar energy generator can be easily installed at homes, schools or business places. The site for installing the solar energy generator is not stringent and does not occupy much space. In addition, the solar energy generator is safe and quiet during operations. In the remote district, the size of the solar energy generator may be specially designed to generate required magnitude of power.

Generally, a solar power module or a photovoltaic module is used to covert solar energy into electric power. The solar power module or the photovoltaic module usually has plural solar cells or photovoltaic cells. The solar cells within the solar power module are connected with each other through slim-type conductive strips, which are also referred as conductive wires. The slim-type conductive strips are exited from the backside of the solar power module. Generally, the slim-type conductive strips are made of copper foil and extended out of the backside of the solar power module (e.g. a solar panel). As known, a junction box is used for electrically connecting the solar cells of the solar power module with each other or electrically connecting the solar power module with other components (e.g. a DC-to-AC converter) of the solar system. The junction box is installed on the backside of the solar panel. A power connecting mechanism is installed within the junction box to be connected with the slim-type conductive strips of the solar power module. Through the junction box, the current generated by the solar power module can be transmitted to the exterior. If the junction box is omitted, the solar power module fails to be normally operated.

Generally, if the light-receiving surface of the solar power module is sheltered or has a small shade, the output power is lowered by about 10% to 25%. The reduction of the output power may result in damage of the solar panel or limit the location of the solar panel. For solving the above drawbacks, a distributed maximum power point tracking (DMPPT) technology has been disclosed. The DMPPT technology automatically adjusts a solar generator's output circuitry to compensate for power fluctuations resulting from varying solar intensity, shadowing, temperature change, panel mismatch, or ageing. The DMPPT technology can compensate each solar panel individually. The DMPPT technology is the most promising technique to improve the energy productivity of photovoltaic systems because it maximizes the power extracted from each panel regardless of adjacent module performance, even if a module has failed.

However, the power connecting mechanism of the current junction box fails to meet the requirements of the DMPPT technology. Moreover, since the power connecting mechanism of the current junction box has a positive output terminal and a negative output terminal, a wiring mechanism should be installed within the junction box in order to transmit power to the power output terminal of the junction box through the power connecting mechanism. Through the wiring mechanism, the positive output terminal of the power connecting mechanism is electrically connected with the positive output terminal of the junction box, and the negative output terminal of the power connecting mechanism is electrically connected with the negative output terminal of the junction box. The additional wiring mechanism increases the complexity of the internal circuitry of the junction box and increases the fabricating cost of the junction box.

### SUMMARY OF THE INVENTION

The present invention provides a junction box having a conductive element for distributing and connecting power, thereby reducing the wiring complexity and the fabricating cost.

The present invention also provides a junction box with a distributed maximum power point tracking (DMPPT) function, in which plural power converting units within the junction box are connected with each other in parallel or in series through at least one conductive element.

The present invention also provides a junction box which has simplified configurations and is easily assembled.

In accordance with an aspect of the present invention, there is provided a junction box. The junction box includes a casing, plural wire-connecting elements, plural power converting units, a first conductive element and a second conductive element. The casing includes an entrance, a first power output terminal and a second power output terminal. The plural wire pairs are introduced into the casing through the entrance. The plural wire-connecting elements are disposed within the casing and connected with corresponding wire pairs. The plural power converting units are detachably connected with corresponding wire-connecting elements. The power converting units include respective first conductive parts and respective second conductive parts. The first conductive element is connected with the first conductive parts of the power converting units and the first power output terminal. The second conductive element is connected with the second conductive parts of the power converting units and the second power output terminal.

In accordance with another aspect of the present invention, there is provided a junction box. The junction box includes a casing, plural wire-connecting elements, plural wire-connecting elements, plural power converting units and at least one conductive element. The casing includes an entrance, a first power output terminal and a second power output terminal. The plural wire pairs are introduced into the casing through the entrance. The plural wire-connecting elements are disposed within the casing and connected with corresponding wire pairs. The plural power converting units are detachably connected with corresponding wire-connecting elements. The power converting units include respective first conductive parts and respective second conductive parts. The first conductive part of a first power converting unit is connected with the first power output terminal. The second conductive part of a last power converting unit is connected with the second power output terminal. A first terminal of the conductive element is connected with the second conductive part of a corresponding power converting unit. A second terminal of the conductive element is connected with the first conductive part of an adjacent power converting unit.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the outward appearance of a junction box for use in a solar power module according to an embodiment of the present invention;

FIG. 2 is a schematic exploded view illustrating the internal portion of the junction box of FIG. 1;

FIG. 3 is a schematic perspective view illustrating a power converting unit of the junction box of FIG. 2;

FIG. 4 is a schematic perspective view illustrating the first conductive element and the second conductive element of the junction box of FIG. 2;

FIG. 5 is a schematic perspective view illustrating the arrangement of the first conductive element and the second conductive element of the junction box of FIG. 2;

FIG. 6 is a schematic exploded view illustrating the internal portion of a junction box according to a second embodiment of the present invention; and

FIG. 7 is a schematic perspective view illustrating the conductive element of the junction box of FIG. 6.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

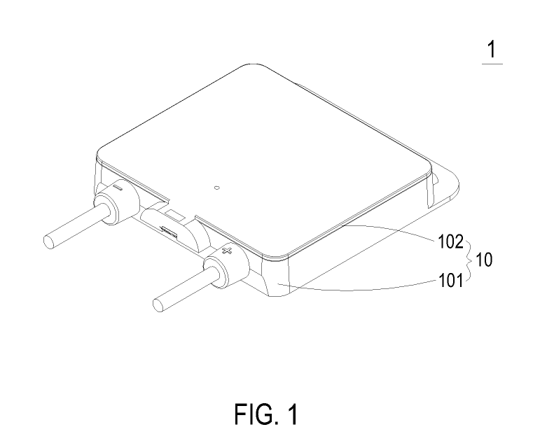

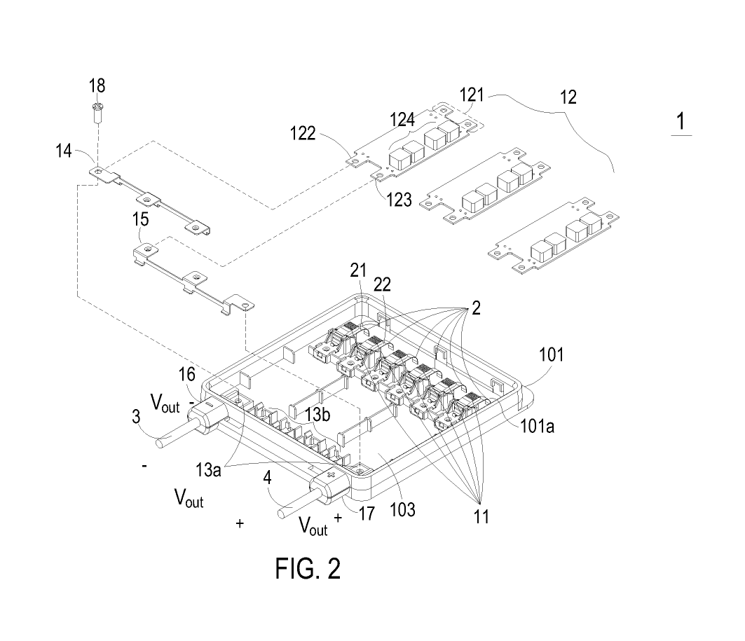

FIG. 1 is a schematic perspective view illustrating the outward appearance of a junction box for use in a solar power module according to an embodiment of the present invention. The junction box has a casing 10 made of a durable plastic material, which is able to withstand stringent weather conditions and has a use life of at least twenty years. In addition, the durable plastic material has an insulating property. As shown in FIG. 1, the casing 10 comprises a base 101 and an upper cover 102. The upper cover 102 is detachably fixed on or engaged with the base 101. The casing 10 has at least one entrance 101a (see FIG. 2) in the bottom of the base 101. Through the entrance, a solar power module may be introduced within the casing 10.

FIG. 2 is a schematic exploded view illustrating the internal portion of the junction box of FIG. 1. The junction box 1 has a distributed maximum power point tracking (DMPPT) function. Moreover, the junction box 1 comprises plural wire-connecting elements 11, plural power converting units 12, a first conductive element 14, a second conductive element 15, a first power output terminal 16 and a second power output terminal 17. The wire-connecting elements 11 are installed within a receiving space 103 of the base 101. Through the entrance 101a of the base 101, the wire-connecting elements 11 are connected with corresponding wire pairs 2. Each wire pair 2 comprises a first wire 21 and a second wire 22 for respectively receiving negative-polarity power and positive-polarity power from the solar power module. The power converting units 12 are disposed within the receiving space 103 of the base 101. Each of the power converting units 12 comprises an input part 121, a first conductive part 122 and a second conductive part 123. Through the input part 121, the power converting unit 12 is detachably and electrically connected with corresponding wire-connecting elements 11. Moreover, each power converting unit 12a comprises plural electronic components 124, which are collectively defined as a power converting circuit for converting power. In this embodiment, the negative-polarity power is outputted from the first conductive part 122, and the positive-polarity power is outputted from the second conductive part 123.

The first conductive element 14 is electrically and structurally connected with the first conductive parts 122 of the power converting units 12 and the first power output terminal 16. The second conductive element 15 is electrically and structurally connected with the second conductive part 123 and the second power output terminal 17. Moreover, two supporting parts 13a and plural holding parts 13b are disposed within the casing 10 and arranged at the locations besides the first power output terminal 16 and the second power output terminal 17. The supporting parts 13a and the holding parts 13b are configured for supporting and fixing the first conductive element 14, the second conductive element 15 and the first conductive parts 122 and the second conductive part 123 of the power converting units 12. The two supporting parts 13a are respectively connected with the contact parts of the first power output terminal 16 and the second power output terminal 17. In addition, the two supporting parts 13a are respectively connected with the first conductive element 14 and the second conductive element 15. The two supporting parts 13a are configured for respectively supporting the first conductive element 14 and the second conductive element 15. The holding parts 13b are used for supporting and fixing the first conductive element 14 and the second conductive element 15. In this embodiment, the first power output terminal 16 and the second power output terminal 17 of the junction box 1 are respectively connected with a first power cord 3 and a second power cord 4.

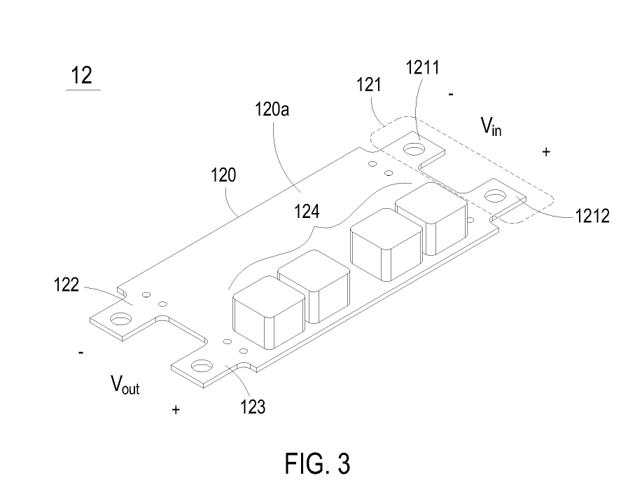

FIG. 3 is a schematic perspective view illustrating a power converting unit of the junction box of FIG. 2. Please refer to FIGS. 2 and 3. The power converting unit 12 further comprises a carrier such as a circuit board. The input part 121 of the power converting unit 12 comprises a first input terminal 1211 and a second input terminal 1212. The first input terminal 1211 and the second input terminal 1212 are connected with corresponding wire-connecting elements 11 in order to receive the negative-polarity power and the positive-polarity power from the first wire 21 and the second wire 22 of a corresponding wire pair 2, respectively. The electronic components 124 are mounted on a surface 120a of the carrier 120. In addition, the electronic components 124 are arranged between the first input terminal 1211, the second input terminal 1212, the first conductive part 122 and the second conductive part 123. These electronic components 124 are collectively defined as a power converting circuit for converting power. An input voltage Vin from the corresponding wire-connecting elements 11 is received by the input part 121 of the power converting unit 12. The input voltage Vin is converted into an output voltage Vout by the electronic components 124. The output voltage Vout is outputted from the first conductive part 122 and the second conductive part 123.

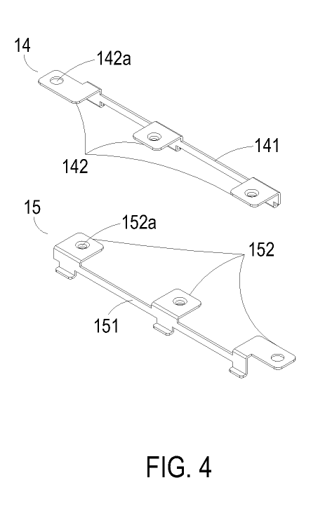

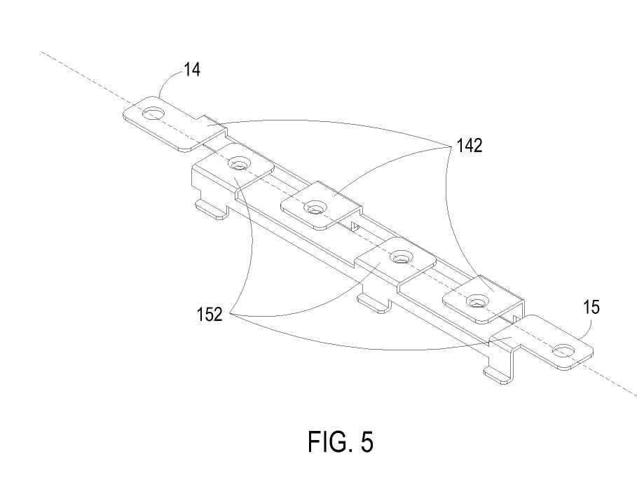

FIG. 4 is a schematic perspective view illustrating the first conductive element and the second conductive element of the junction box of FIG. 2. Please refer to FIGS. 2 and 4. The first conductive element 14 has a first bus bar 141 and plural first extension parts 142. The first extension parts 142 are extended from the first bus bar 141 and discretely arranged at regular intervals. Through the first extension parts 142, the first conductive element 14 is structurally and electrically connected with the first conductive parts 122 of the power converting units 12 and the first power output terminal 16. That is, the first conductive element 14 is configured for receiving the negative-polarity voltage (Vout−) from the first conductive parts 122, and transmitted the negative-polarity voltage (Vout−) to the first power output terminal 16. Moreover, the first conductive element 14 is structurally and electrically connected with the first power output terminal 16 through either of the first extension parts 142. The second conductive element 15 has a second bus bar 151 and plural second extension parts 152. The second extension parts 152 are extended from the second bus bar 151 and discretely arranged at regular intervals. Through the second extension parts 152, the second conductive element 15 is structurally and electrically connected with the second conductive parts 123 of the power converting units 12 and the second power output terminal 17. That is, the second conductive element 15 is configured for receiving the positive-polarity voltage (Vout+) from the second conductive parts 123, and transmitted the positive-polarity voltage (Vout+) to the second power output terminal 17. Moreover, the second conductive element 15 is structurally and electrically connected with the second power output terminal 17 through either of the second extension parts 152. In this embodiment, the first conductive element 14 is separated from the second conductive element 15. FIG. 5 is a schematic perspective view illustrating the arrangement of the first conductive element and the second conductive element of the junction box of FIG. 2. Please refer to FIG. 5. Preferably, the first extension parts 142 of the first conductive element 14 and the second extension parts 152 of the second conductive element 15 are arranged in a line. Moreover, the first extension parts 142 and the second extension parts 152 are arranged in a staggered form. The first conductive parts 122 of the plural power converting units 12 are connected with the first power output terminal 16 through the first conductive element 14. In addition, the second conductive parts 123 of the plural power converting units 12 are connected with the second power output terminal 17 through the second conductive element 15. In such way, the power converting units 12 are connected with each in parallel.

In this embodiment, the plural first extension parts 142 of the first conductive element 14 and the plural second extension parts 152 of the second conductive element 15 have respective perforations 142a and 152a. The junction box 1 further comprises plural fastening elements 18 (see FIG. 2) such as screws. After the fastening elements 18 are penetrated through the perforations 142a and 152a, the first conductive element 14, the second conductive element 15 and the first conductive parts 122 and the second conductive parts 123 of the power converting units 12 are fixed within the junction box 1. In other words, the first conductive parts 122 of the power converting units 12 are connected with and fixed on the first conductive element 14, and the second conductive parts 123 of the power converting units 12 are connected with and fixed on the second conductive element 15. In some embodiments, respective washers (not shown) are disposed between the first conductive parts 122 of the power converting units 12 and the first extension parts 142 of the first conductive element 14 and between the second conductive parts 123 of the power converting units 12 and the second extension parts 152 of the second conductive element 15. The washers are made of a conductive material. Through the washers, the first conductive parts 122 of the power converting units 12 are tightly fixed on the first extension parts 142 of the first conductive element 14, and the second conductive parts 123 of the power converting units 12 are tightly fixed on the second extension parts 152 of the second conductive element 15.

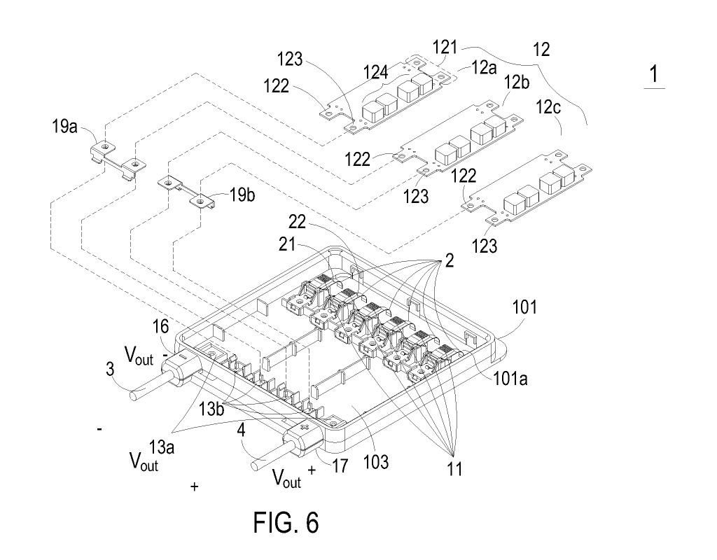

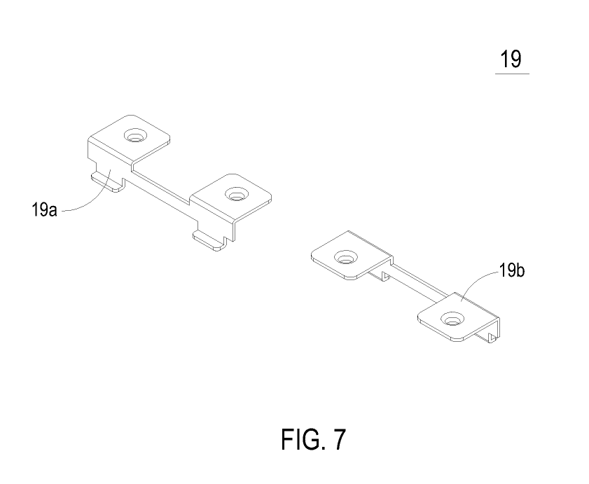

FIG. 6 is a schematic exploded view illustrating the internal portion of a junction box according to a second embodiment of the present invention. FIG. 7 is a schematic perspective view illustrating the conductive element of the junction box of FIG. 6. In this embodiment, the junction box 1 also has a distributed maximum power point tracking (DMPPT) function. The junction box 1 comprises a casing 10, plural wire-connecting elements 11, plural power converting units 12, at least one conductive element 19, a first power output terminal 16 and a second power output terminal 17. The configurations and functions of the casing 10, the wire-connecting elements 11, the power converting units 12, the first power output terminal 16 and the second power output terminal 17 included in this embodiment are similar to those of FIG. 2, and are not redundantly described herein. The first conductive part 122 of the first power converting unit 12a is connected with the first power output terminal 16. The second conductive part 123 of the last power converting unit 12c is connected with the second power output terminal 17. A first terminal of each conductive element 19 is connected with the second conductive part 123 of a corresponding power converting unit. In addition, a second terminal of each conductive element 19 is connected with the first conductive part 122 of an adjacent power converting unit.

In this embodiment, the power converting units 12 comprises the first power converting unit 12a, the second power converting unit 12b and the last power converting unit 12c. The at least one conductive element 19 comprises a first conductive element 19a and a second conductive element 19b. The first conductive element 19a is connected with the second conductive part 123 of the first power converting unit 12a and the first conductive part 122 of the second power converting unit 12b. The second conductive element 19b is connected with the second conductive part 123 of the second power converting unit 12b and the first conductive part 122 of the last power converting unit 12c. In such way, the power converting units 12 are connected with each in series through the at least one conductive element 19.

From the above description, the junction box of the present invention has a simplified configuration and is cost-effective. Moreover, the junction box is easily installed and maintained. Through the conductive elements, the power converting units may be electrically connected with the first power output terminal and the second power output terminal in parallel or in series. The power converted by the power converting units is then distributed and outputted to the loads. Moreover, since the power converting units are directly installed within the junction box, the space between a solar power module or a photovoltaic module and the load will be reduced. Moreover, the junction box can be applied to a solar power module or a photovoltaic module while maintaining reliable electrical connection.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A junction box, comprising:
a casing comprising an entrance, a first power output terminal and a second power output terminal, wherein plural wire pairs are introduced into said casing through said entrance;
plural wire-connecting elements disposed within said casing and connected with corresponding wire pairs;
plural power converting units detachably connected with corresponding wire-connecting elements, wherein said power converting units comprise respective first conductive parts and respective second conductive parts;
a first conductive element connected with said first conductive parts of said power converting units and said first power output terminal; and
a second conductive element connected with said second conductive parts of said power converting units and said second power output terminal.

2. The junction box according to claim 1 wherein each of said power converting units comprises:
a carrier;
an input part comprising a first input terminal and a second input terminal, which are respectively connected with two of said plural wire-connecting elements; and
plural electronic components mounted on a surface of said carrier, and arranged between said first input terminal, said second input terminal, said first conductive part and said second conductive part.

3. The junction box according to claim 1 wherein said first conductive element comprises:
a first bus bar for distributing power from said first conductive parts of said power converting units; and
plural first extension parts extended from said first bus bar, and structurally and electrically connected with said first conductive parts of said power converting units and said first power output terminal for receiving power from said first conductive parts.

4. The junction box according to claim 3 wherein said second conductive element comprises:
a second bus bar for distributing power from said second conductive parts of said power converting units; and
plural second extension parts extended from said second bus bar, and structurally and electrically connected with said second conductive parts of said power converting units and said second power output terminal for receiving power from said second conductive parts.

5. The junction box according to claim 4 wherein said first extension parts and said second extension parts have respective perforations.

6. The junction box according to claim 4 wherein said first extension parts of said first conductive element and said second extension parts of said second conductive element are arranged in a staggered form.

7. The junction box according to claim 4 wherein said first extension parts of said first conductive element and second extension parts of said second conductive element are arranged in a line.

8. The junction box according to claim 1 wherein said first conductive parts and said second conductive parts of said power converting units are connected with each in parallel through said first conductive element and said second conductive element.

9. The junction box according to claim 1 wherein said casing further comprises two supporting parts and plural holding parts for supporting and fixing said first conductive element, said second conductive element and said first conductive parts and said second conductive part of said power converting units.

10. The junction box according to claim 1 further comprising plural fastening elements for fixing said first conductive element, said second conductive element and said first conductive parts and said second conductive part of said power converting units.

11. A junction box, comprising:
a casing comprising an entrance, a first power output terminal and a second power output terminal, wherein plural wire pairs are introduced into said casing through said entrance;
plural wire-connecting elements disposed within said casing and connected with corresponding wire pairs;
plural power converting units detachably connected with corresponding wire-connecting elements, wherein said power converting units comprise respective first conductive parts and respective second conductive parts, wherein said first conductive part of a first power converting unit is connected with said first power output terminal, and said second conductive part of a last power converting unit is connected with said second power output terminal; and
at least one conductive element, wherein a first terminal of said conductive element is connected with said second conductive part of a corresponding power converting unit, and a second terminal of said conductive element is connected with said first conductive part of an adjacent power converting unit.

12. The junction box according to claim 11 wherein said power converting units are connected with each other in series through said at least one conductive element.

13. The junction box according to claim 11 wherein said plural power converting units comprises said first power converting unit, a second power converting unit and said last power converting unit, wherein said conductive element comprises a first conductive element and a second conductive element, wherein said first conductive element is connected with said second conductive part of said first power converting unit and said first conductive part of said second power converting unit, and said second conductive element is connected with said second conductive part of said second power converting unit and said first conductive part of said last power converting unit.
